(19) United States
(12) Patent Application Publication
(10) Pub. No.: US 2026/0234797 A1
(43) Pub. Date: Aug. 13, 2026

(54) PROCESS CHAMBER GAS FLOW IMPROVEMENT

(71) Applicant: Applied Materials, Inc., Santa Clara, CA (US)

(72) Inventors: Martin Jeffrey SALINAS, San Jose, CA (US); Shu-Kwan LAU, Sunnyvale, CA (US)

(21) Appl. No.: 19/053,018

(22) Filed: Feb. 13, 2025

(51) Int. Cl. H01J 37/32; H01L 21/67

(52) U.S. Cl. CPC H01J 37/32449; H10P 72/0404; H01J 2237/3323

(57) ABSTRACT

A processing system is provided that includes a process chamber and a gas supply system. The process chamber includes: a chamber body disposed around an interior volume; a substrate support positioned in the interior volume; a plurality of gas injectors configured to direct gas into a first region of the interior volume; and an exhaust channel configured to exhaust gas from a second region of the interior volume. The gas supply system includes a main gas line coupled with a plurality of gas sources that include a first gas source; a plurality of gas lines, each gas line of the plurality of gas lines coupled between the main gas line and one of the gas injectors; and one or more auxiliary gas lines including a first auxiliary gas line coupled between the first gas source and a first gas line of the plurality of gas lines.

### BACKGROUND

### Field

Embodiments of the present disclosure generally relate to improved process chambers for processing of substrates, such as semiconductor substrates. More particularly, the improvements relate to gas delivery features of the process chambers that improve the uniformity of the process performed on the substrate, such as a deposition.

### Description of the Related Art

Substrates, such as semiconductor substrates, are positioned on substrate supports in process chambers during processes, such as deposition or etching processes. Gas is typically provided to process chambers from (1) above the substrate support using a showerhead or (2) from one side of the substrate support using a cross-flow configuration where the gas is exhausted on the opposing side of the substrate support. Some processes, such as epitaxy, have obtained better results using the cross-flow configuration for the gas flow through the interior of the chamber. When gas is delivered to the process chamber on one side and exhausted on the other side using the cross-flow configuration, the substrate support is generally rotated to ensure that each portion of the substrate is exposed to substantially the same concentrations of gases, which helps achieve process uniformity, such as deposition thickness uniformity.

Although improvements to process uniformity have been achieved over the years for processes using cross-flow configuration for the gas flow, non-uniformities persist. Thus, there is an ongoing need to improve process uniformity for processes performed in process chambers using the cross-flow configuration for the gas flow, such as depositions processes.

### SUMMARY

The present disclosure generally relates to improved process chambers for processing of substrates, such as semiconductor substrates. More particularly, the improvements relate to gas delivery features of the process chambers that improve the uniformity of the process performed on the substrate, such as a deposition.

In one embodiment, a processing system is provided comprising: a process chamber comprising: a chamber body disposed around an interior volume; a substrate support positioned in the interior volume; a plurality of gas injectors configured to direct gas into a first region of the interior volume, each gas injector positioned at a different angular location relative to a central vertical axis extending through a center of the substrate support; and an exhaust channel configured to exhaust gas from a second region of the interior volume, the first region and the second region located on opposing sides of the central vertical axis; and a gas supply system comprising a main gas line coupled with a plurality of gas sources that include a first gas source and a second gas source; a plurality of gas lines, each gas line of the plurality of gas lines coupled between the main gas line and one of the gas injectors; and one or more auxiliary gas lines including a first auxiliary gas line coupled between the first gas source and a first gas line of the plurality of gas lines.

In another embodiment, a processing system is provided comprising: a process chamber comprising: a chamber body disposed around an interior volume; a substrate support positioned in the interior volume; and a plurality of gas injectors configured to direct gas into the interior volume, each gas injector positioned at a different angular location relative to a central vertical axis extending through a center of the substrate support; a gas supply system comprising a main gas line coupled with a plurality of gas sources that include a first gas source and a second gas source; a plurality of gas lines, each gas line of the plurality of gas lines coupled between the main gas line and one of the gas injectors; and one or more auxiliary gas lines including a first auxiliary gas line coupled between the first gas source and a first gas line of the plurality of gas lines; and a controller configured to: provide a first gas from the first gas source and a second gas from the second gas source to the first gas line through the main gas line; and provide the first gas from the first gas source to the first gas line through the first auxiliary gas line without going through the main gas line.

In another embodiment, a method of processing a substrate is provided comprising: positioning a substrate on a substrate support in an interior volume of a process chamber, the process chamber comprising a plurality of gas injectors configured to direct gas into the interior volume, each gas injector positioned at a different angular location relative to a central vertical axis extending through a center of the substrate support; providing a mixture of a first gas from a first gas source and a second gas from a second gas source to a first gas line and a second gas line of a plurality of gas lines through a main gas line, wherein each gas line of the plurality of gas lines is coupled between the main gas line and one of the gas injectors; providing the first gas from the first gas source to the first gas line through a first auxiliary gas line without having the flow from first auxiliary gas line go through the main gas line; and directing a flow of the first gas and the second gas into the interior volume of the process chamber through the plurality of gas injectors.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1A is a cross-sectional view of a processing system, according to one embodiment.

FIG. 1B is a top schematic view of the processing system from FIG. 1A, according to one embodiment.

FIG. 2 is a process flow diagram of a method for processing a substrate in the processing system 100 from FIG. 1A, according to one embodiment.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to equipment and related methods for improving the uniformity of processes performed on substrates in process chambers, such as epitaxial depositions and other processes in which a cross-flow configuration is used for the gas flow to the process chamber. The improvements disclosed herein are obtained by (1) providing a same mixture of gases to a plurality of gas lines that are each fluidly coupled with a different gas injector of the process chamber, and (2) providing a relatively small flow of one more gases to one or more of the gas lines that have the mixture of gases flow through to the gas injectors. This relatively small flow of gases can be used to make fine adjustments to the concentrations of gases provided through the corresponding gas line, so that fine adjustments to the concentration of gases provided to the different injectors can be made. Because each gas that is injected directs the gases over a different region of the substrate, the concentrations of gases over the different regions of the substrate can be adjusted using the methods disclosed herein.

These fine adjustments of the concentration of gases over the substrate can be used to address non-uniformities of the process being performed on the substrate. For example, a relatively small addition of precursor gas can be used to increase the deposition rate over a region of the substrate that has a deposition rate that is lower than a targeted level. On the other hand, a relatively small addition of a carrier gas or inert gas can be used to reduce the deposition rate over a region of the substrate that has a deposition rate that is higher than a targeted level.

Although the following disclosure mainly describes improvements in equipment and methods for improving process uniformity for depositions performed on substrates in an epitaxial deposition chamber, the benefits of this disclosure can also be applied to other deposition chambers (e.g., chemical vapor deposition (CVD) chambers or plasma enhanced CVD chambers) as well as to process chambers configured to perform different processes, such as etching. More generally, the benefits of this disclosure can apply to any process that provides gas to a process chamber through independent flow paths to different regions over a substrate whether using a cross-flow configuration or showerhead configuration for the main gas flow.

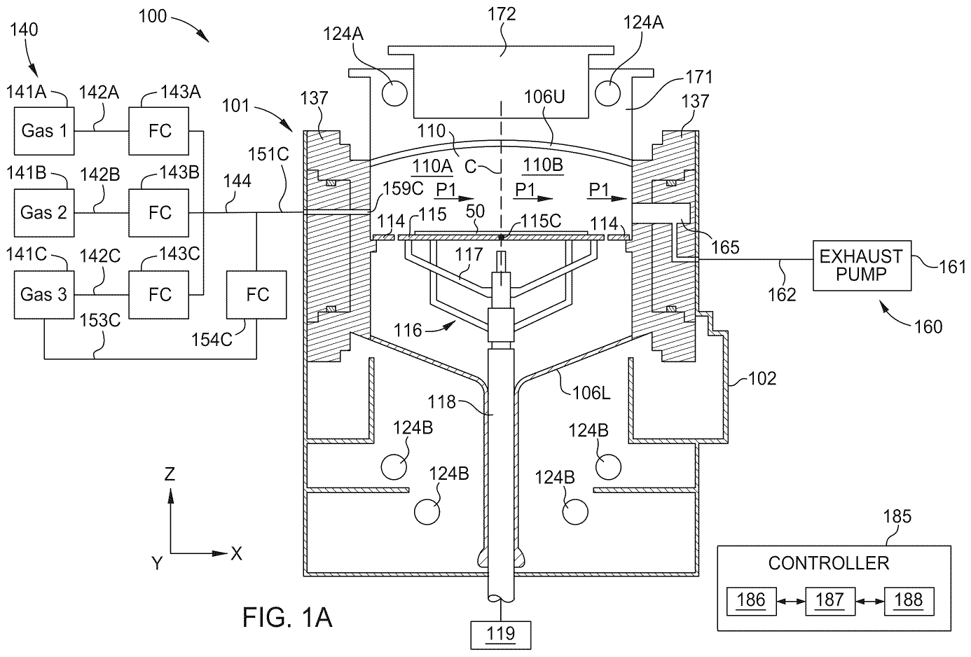

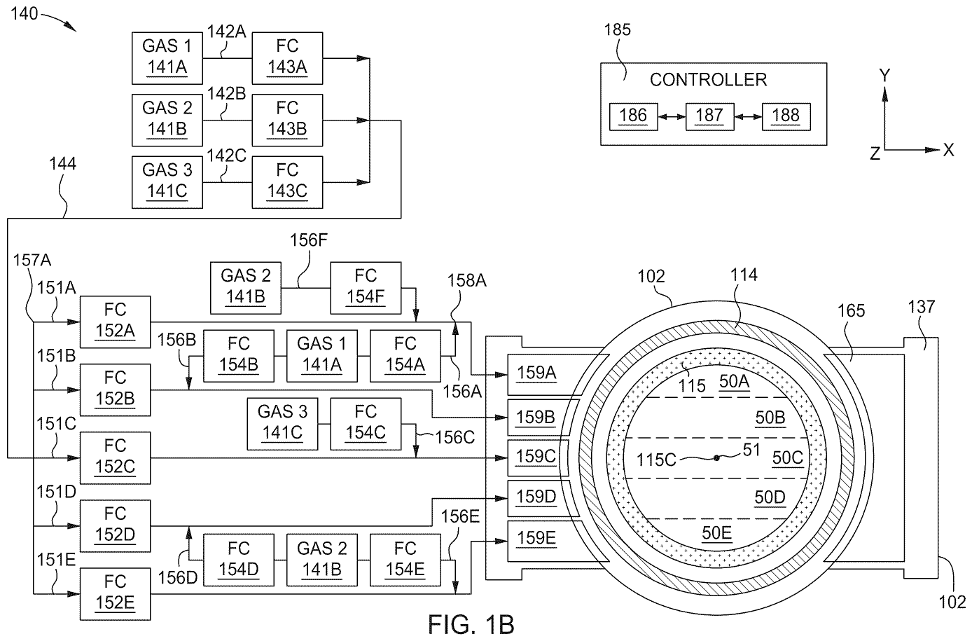

FIG. 1A is a cross-sectional view of a processing system 100, according to one embodiment. The processing system 100 includes a process chamber 101, a gas supply system 140, an exhaust system 160, and a controller 185. A substrate 50 is shown positioned on a substrate support in an interior volume 110 of the process chamber 101. The processing system 100 can be configured to perform epitaxial deposition processes on the substrate 50 in the process chamber 101 as well as other processes, such as cleaning or etching processes.

The process chamber 101 includes a chamber body 102. In some embodiments, the chamber body 102 can be made of a process resistant material, such as aluminum or stainless steel, for example 316L stainless steel. The chamber body 102 is disposed around structural components of the process chamber 101, such as an upper window 106U, a lower window 106L, and a liner 137. In one embodiment, the windows 106U, 106L can each be formed of quartz. The liner 137 can be positioned between the windows 106U, 106L and the chamber body 102 to insulate the windows 106U, 106L from the chamber body 102. The windows 106U, 106L and the liner 137 enclose the interior volume 110 (also referred to as process volume) of the process chamber 101.

The process chamber 101 further includes a substrate support assembly 116. The substrate support assembly 116 can include supports 117 and a shaft 118. A susceptor 115 (also referred to as substrate support) can be positioned on the supports 117. The substrate 50 is positioned on the susceptor 115 during processing, such as during an epitaxial deposition. The substrate support assembly 116 can further include an actuator 119 coupled to the shaft 118. The actuator 119 can be used to raise and lower the susceptor 115, for example to facilitate insertion and removal of the substrate 50. The actuator 119 can also be used to rotate the shaft 118 and susceptor 115 about a central vertical axis C that extends through a center 115C of the susceptor 115. This rotation enables the substrate 50 to be rotated during processing, which improves process uniformity. The process chamber 101 can further include a preheat ring 114 that can be positioned on a ledge of the liner 137. The preheat ring 114 extends around the susceptor 115.

The process chamber 101 can further include upper lamp modules 124A and lower lamp modules 124B for heating of the substrate 50 and/or the interior volume 110. In one embodiment, the upper lamp modules 124A and the lower lamp modules 124B are infrared (IR) lamps.

The process chamber 101 further includes an outer reflector 171 and an inner reflector 172 positioned over the upper window 106U. The outer reflector 171 can be positioned around the inner reflector 172. In some embodiments, one or more upper lamp modules 124A can be positioned inside the outer reflector 171.

The gas supply system 140 is used to direct process gases along a gas flow path P1 over the substrate 50 during the process. As described in further detail below, the process chamber 101 includes a plurality of gas injectors 159 positioned at different angular locations around the susceptor 115 to direct gases over different portions of the substrate 50. One gas injector 159C is shown in FIG. 1A. Additional components of the gas supply system 140 are shown in FIG. 1B.

The gas injectors 159 can extend through the liner 137 to provide a gas flow path into the interior volume 110 for the gas provided by the gas supply system 140. The gas injectors 159 can be positioned at a vertical location above the susceptor 115, so that the process gas is directed from the gas injectors 159 and over the substrate 50 positioned on the susceptor 115. The gas injectors 159 can be positioned at different angular locations relative to the central vertical axis C extending through the center 115C of the susceptor 115 as shown in FIG. 1B.

The gas supply system 140 includes a first gas source 141A, a second gas source 141B, and a third gas source 141C. In some embodiments, the first gas source 141A stores a first precursor gas (e.g., silane), the second gas source 141B stores a second precursor gas (e.g., phosphene or another gas including a dopant) or an etchant (e.g., hydrogen chloride gas), and the third gas source 141C stores a carrier gas (e.g., hydrogen).

The gas supply system 140 further includes a first supply line 142A and a first flow controller 143A located on the first supply line 142A. The first supply line 142A is fluidly coupled to the first gas source 141A. The first flow controller 143A can be used to adjust the amount of first precursor gas supplied to the mixture of gases that are supplied to the interior volume 110 process chamber 101.

Used herein, a flow controller (e.g., a mass flow controller) refers to one or more devices that include at least one sensor (e.g., a mass flow sensor) for measuring a flowrate, at least one valve for adjusting the flow of the corresponding gas, and at least one controller for controlling the position of the valve based on the flowrate measurement from the sensor. The flow controller can be a dedicated controller for one or more flow controllers described herein, or the controller 185 that is communication with the sensor and valve for each flow controller. Used herein, the term controller can collectively include the controller 185 along with any other controllers, such as the flow controllers.

The gas supply system 140 further includes a second supply line 142B and a second flow controller 143B located on the second supply line 142B. The second supply line 142B is fluidly coupled to the second gas source 141B. The second flow controller 143B can be used to adjust the amount of second precursor gas supplied to the mixture of gases that are supplied to the interior volume 110 process chamber 101.

The gas supply system 140 further includes a third supply line 142C and a third flow controller 143C located on the third supply line 142C. The third supply line 142C is fluidly coupled to the third gas source 141C. The third flow controller 143C can be used to adjust the amount of the carrier gas supplied to the mixture of gases that are supplied to the interior volume 110 process chamber 101.

The gas supply system 140 further includes a main gas line 144 that is fluidly coupled with each of the gas sources 141 through the first supply line 142A, the second supply line 142B, and the third supply line 142C. The main gas line 144 is downstream of the first supply line 142A, the second supply line 142B, and the third supply line 142C. The gases from each of the gas sources 141A, 141B, 141C mix together in the main gas line 144. The flow controllers 143A, 143B, 143C are used to control the flow of each corresponding gas to the main gas line 144 enabling a mixture with targeted proportions of each gas to be obtained.

The gas supply system 140 further includes a plurality of gas lines 151 that are fluidly coupled with the main gas line 144. Each gas line 151 is fluidly coupled to one of the gas injectors 159. A single gas injector 159C is shown in FIG. 1A. Each gas injector 159 directs gas over a different region of the substrate 50 as described in further detail in reference to FIG. 1B.

Each gas line 151 can be further coupled with at least one of the gas sources 141 through an auxiliary gas line to enable fine adjustments to the flow of at least one of the gases flowing through the corresponding gas line 151. In some embodiments, one or more of the gas lines 151 are not coupled to one of the gas sources 141 through an auxiliary gas line. FIG. 1A shows that the gas line 151C is fluidly coupled with the third gas source 141C through an auxiliary gas line 153C. A flow controller 154C is positioned on the auxiliary gas line 153C to control the flow of the gas provided to the gas line 151C through the auxiliary gas line 153C.

The exhaust system 160 includes an exhaust pump 161 and an exhaust line 162. The exhaust line 162 fluidly couples the exhaust pump 161 to an exhaust channel 165 of the process chamber 101. The exhaust channel 165 is fluidly coupled to the interior volume 110.

The exhaust channel 165 is positioned on an opposite side of the process chamber 101 relative to the gas injectors 159. The gas injectors 159 can be horizontally spaced apart from the susceptor 115 in the X-direction (first direction). The relative locations of the gas injectors 159 and the exhaust channel 165 causes the gas from the gas injectors 159 to flow along the main gas flow path P1 over the substrate 50. The main gas flow path P1 can be a substantially horizontal gas flow path, such as being within about plus or minus 15 degrees from horizontal. The gas injectors 159 are configured to direct gas into a first region 110A of the interior volume 110. The gas then flows into a second region 110B of the interior volume 110. The exhaust channel 165 is configured to exhaust gas from the second region 110B of the interior volume 110. The first region 110A and the second region 110B are located on opposing sides of the central vertical axis C extending through the center 115C of the susceptor 115.

The processing system 100 also includes the controller 185 for controlling processes performed by the processing system 100. The controller 185 can be any type of controller used in an industrial setting, such as a programmable logic controller (PLC). The controller 185 includes a processor 187, a memory 186, and input/output (I/O) circuits 188. The controller 185 can further include one or more of the following components (not shown), such as one or more power supplies, clocks, communication components (e.g., network interface card), and user interfaces typically found in controllers for semiconductor equipment.

The memory 186 can include non-transitory memory. The non-transitory memory can be used to store the programs and settings described below. The memory 186 can include one or more readily available types of memory, such as read only memory (ROM) (e.g., electrically erasable programmable read-only memory (EEPROM), flash memory, floppy disk, hard disk, or random access memory (RAM) (e.g., non-volatile random access memory (NVRAM).

The processor 187 is configured to execute various programs stored in the memory 186, such as epitaxial deposition processes and other processes. During execution of these programs, the controller 185 can communicate to I/O devices through the I/O circuits 188. For example, during execution of these programs and communication through the I/O circuits 188, the controller 185 can receive inputs (e.g., flowrate measurements from flow sensors) and control outputs, such as the position of valves (e.g., valves that part of the flow controllers) to send process gases to the interior volume 110 of the process chamber 101 or to perform other processes. The memory 186 can further include various operational settings used to control the processing system 100. For example, the settings can include durations for how long the different valves remain open or closed during different depositions and other processes and setpoints for the flowrate of the different gases to be provided through the corresponding gas lines.

FIG. 1B is a top schematic view of the processing system 100 from FIG. 1A, according to one embodiment. FIG. 1B shows additional detail on the gas supply system 140. The following is described with reference to FIG. 1A and FIG. 1B.

The process chamber 101 includes five gas injectors 159A-159E. The gas supply system 140 includes five gas lines 151. Each gas injector 159 is fluidly coupled with one of the gas lines 151, so that the gas flow to each gas injector 159 can be independently controlled by the flow through one of the gas lines 151. Each gas line 151 receives a portion of the mixture of gases from the gas sources 141 that are directed through the main gas line 144. Each gas line 151 includes a main gas inlet 157 where the gas line 151 receives the mixture of gases from the main gas line 144. Each gas line 151 is configured to receive a same gas mixture from the main gas line 144 at the corresponding main gas inlet 157. Only, a main gas inlet 157A on the first gas line 151A is labeled in FIG. 1B to avoid cluttering the drawing.

The gas supply system 140 further includes a flow controller 152 on each gas line 151. The flow controllers 152 control the portion of the flow provided to the main gas line 144 that is provided to each gas line 151.

The flow to each gas injector 159 is independently controlled. Each gas injector 159 is located at a different angular position relative to the center 115C of the susceptor 115, so that the flow of gas can be controlled over different portions of the susceptor 115 and substrate 50. For example, the first gas injector 159A can direct gas over a first region 50A of the susceptor 115 and substrate 50, the second gas injector 159B can direct gas over a second region 50B of the susceptor 115 and substrate 50, the third gas injector 159C can direct gas over a third region 50C of the susceptor 115 and substrate 50, the fourth gas injector 159D can direct gas over a fourth region 50D of the susceptor 115 and substrate 50, and the fifth gas injector 159E can direct gas over a fifth region 50E of the susceptor 115 and substrate 50. Although five gas injectors 159 are shown in FIG. 1B, other embodiments can have fewer or more independently controlled gas injectors.

The gas supply system 140 further includes six auxiliary gas lines 156A-156F. The auxiliary gas lines 156 are used to make fine adjustments to the concentrations of gases in the mixtures provided to the gas lines 151 by the main gas line 144. Each auxiliary gas line 156 supplies one gas from the gas sources 141 to a corresponding gas line 151 without going through the main gas line 144. In some embodiments, two or more auxiliary gas lines can be coupled with a single gas line 151 or a single auxiliary gas line can be coupled with two or more gas sources, so that the concentration of two or more of the gases in the gas mixture in the corresponding gas line 151 can be adjusted. The gas supply system 140 further includes six auxiliary flow controllers 154A-154F. Each auxiliary flow controller 154 is positioned on one of the auxiliary gas lines 156 to control the flow of gas through that auxiliary gas line 156 to the corresponding gas line 151. Each gas line 151 is coupled with an auxiliary gas line 156 at an auxiliary gas inlet 158. Only, an auxiliary gas inlet 158A on the first gas line 151A is labeled in FIG. 1B to avoid cluttering the drawing. Each auxiliary gas inlet 158 is downstream of the main gas inlet 157 for that gas line 151.

The first auxiliary gas line 156A fluidly couples the first gas source 141A with the first gas line 151A to provide an additional flow of the first precursor gas to interior volume 110 through the first gas injector 159A. The first gas source 141A as well as the other gas sources 141B, 141C are shown in two different locations in FIG. 1B to avoid cluttering the drawing with gas lines crossing over each other. This additional flow of first precursor gas through the first gas line 151A from the first auxiliary gas line 156A is controlled by the first auxiliary flow controller 154A and can increase the deposition rate over the first region 50A of the substrate 50. This increased deposition rate can be useful when the first region 50A has a deposition rate that is below the deposition rate of one or more of the other regions of the substrate 50 when no additional first precursor gas is provided to the first gas line 151A by the first auxiliary gas line 156A.

The second auxiliary gas line 156B fluidly couples the first gas source 141A with the second gas line 151B to provide an additional flow of the first precursor gas to interior volume 110 through the second gas injector 159B. This additional flow of first precursor gas through the second gas line 151B from the second auxiliary gas line 156B is controlled by the second auxiliary flow controller 154B and can increase the deposition rate over the second region 50B of the substrate 50. This increased deposition rate can be useful when the second region 50B has a deposition rate that is below the deposition rate of one or more of the other regions of the substrate 50 when no additional first precursor gas is provided to the second gas line 151B by the second auxiliary gas line 156B.

The third auxiliary gas line 156C fluidly couples the third gas source 141C with the third gas line 151C to provide an additional flow of the carrier gas to interior volume 110 through the third gas injector 159C. This additional flow of carrier gas from the auxiliary gas line 156C is controlled by the third auxiliary flow controller 154C and can decrease the deposition rate over the third region 50C of the substrate 50 by diluting the concentration of the precursor gases in the third gas line 151C. This decreased deposition rate can be useful when the third region 50C has a deposition rate that is greater than the deposition rate of one or more of the other regions of the substrate 50 when no additional carrier gas is provided to the third gas line 151C by the third auxiliary gas line 156C.

The fourth auxiliary gas line 156D fluidly couples the second gas source 141B with the fourth gas line 151D to provide an additional flow of the second precursor gas to interior volume 110 through the fourth gas injector 159D. This additional flow of second precursor gas through the fourth gas line 151D from the fourth auxiliary gas line 156D is controlled by the fourth auxiliary flow controller 154D and can increase the deposition rate over the fourth region 50D of the substrate 50. This can be useful when the fourth region 50D has a deposition rate that is below the deposition rate of one or more of the other regions of the substrate 50 when no additional second precursor gas is provided to the fourth gas line 151D by the fourth auxiliary gas line 156D.

The fifth auxiliary gas line 156E fluidly couples the second gas source 141B with the fifth gas line 151E to provide an additional flow of the second precursor gas to interior volume 110 through the fifth gas injector 159E. This additional flow of second precursor gas through the fifth gas line 151E from the fifth auxiliary gas line 156E is controlled by the fifth auxiliary flow controller 154E and can increase the deposition rate over the fifth region 50E of the substrate 50. This can be useful when the fifth region 50E has a deposition rate that is below the deposition rate of one or more of the other regions of the substrate 50 when no additional second precursor gas is provided to the fifth gas line 151E by the fifth auxiliary gas line 156E.

The sixth auxiliary gas line 156F fluidly couples the second gas source 141B with the first gas line 151A to provide an additional flow of the second precursor gas to interior volume 110 through the first gas injector 159A. Thus, the first gas line 151A is coupled to the first gas source 141A through the first auxiliary gas line 156A and to the second gas source 141B through the sixth auxiliary gas line 156F. Providing two precursor gases to one gas line 151 through one or more auxiliary gas lines 156 can be useful when the process rate is controlled more effectively by increasing the concentrations of two precursor gases as opposed to a single precursor gas.

The additional flow of second precursor gas through the first gas line 151A from the sixth auxiliary gas line 156F is controlled by the sixth auxiliary flow controller 154F and can increase the deposition rate over the first region 50A of the substrate 50. This increased deposition rate can be useful when the first region 50A has a deposition rate that is below the deposition rate of one or more of the other regions of the substrate 50 when no additional second precursor gas is provided to the first gas line 151A by the sixth auxiliary gas line 156F.

The auxiliary gas lines 156 can be used to make fine adjustments to the composition of the mixture provided to the gas lines 151 from the main gas line 144. Although the main gas line 144 provides a mixture having a uniform composition of gases to each gas line 151, the deposition rate still varies across the substrate 50, for example at different radial locations across the substrate 50. These deposition rate variations can lead to lower product quality and device performance, especially as dimensions on semiconductor devices and similar components continue to shrink.

The auxiliary gas lines 156 allow fine adjustments to be made to the mixture provided from each of the gas lines 151 to the corresponding gas injector 159. Thus, a gas flow with a different composition can be provided over different regions of the substrate 50, such as the regions 50A-50E shown in FIG. 1B. These different gas flows with different compositions provided to the different gas injectors 159 can be used to improve the deposition uniformity across the substrate 50 as the regions with lower than targeted deposition rates receive additional precursor to increase the deposition rate and the regions with higher than targeted deposition rates receive additional carrier gas or inert gas to dilute the precursor composition and decrease the deposition rate. In some embodiments, which can be combined with other embodiments, the flowrate provided by each auxiliary gas line 156 is from about 0.1% to about 10%, such as from about 1% to about 5% of the total flowrate of gases being directed through the gas line 151 to which the auxiliary gas line 156 is fluidly coupled.

The velocity profile of the gases over the substrate 50 can also be an important factor in achieving a targeted deposition rate and deposition uniformity. Used herein, the velocity profile is how the velocity of gases provided to the interior volume change in the vertical direction over different regions of the substrate 50. The substrate 50 can cause some drag and reduce the velocity of the gas directly over the substrate 50 while gases further above the substrate 50 and sufficiently spaced apart from the overhead components, such as window 106U, can have a faster velocity.

A flatter velocity profile over the substrate can improve the deposition rate as more fresh precursor gas has an opportunity to interact with the substrate 50. On the other hand, a velocity profile with a larger variation in velocities can lead to a reduced deposition rate and wasted process gases as gases with the highest velocities are directed towards the exhaust channel 165 without having the opportunity to interact with the substrate 50, which can increase production costs. Directing precursor gases towards the exhaust channel 165 at high velocities without having an opportunity to interact with the substrate leads to a significant variation in the concentration profile of gases in the vertical direction as the gases flow towards regions overlying portions of the substrate 50 near the exhaust channel 165 with high concentrations of fresh precursor gas remaining at vertical locations spaced apart from the substrate 50.

In the absence of any other changes to the process, the relatively small additions of gas flows provided by the auxiliary gas lines 156 can be sufficient to alter the velocity profile of the gases over the substrate 50 in a way that negatively impacts the deposition rate or gas utilization rate. To avoid these negative impacts by the small additions of gas to the auxiliary gas lines, the flowrates provided to the gas lines 151 by the main gas line 144 can be reduced by an amount that allows the total flow provided by the gas injector 159 to remain the same as it was before the addition of gas provided by the auxiliary gas line 156.

The following tables can provide an illustrative example of how the flows can be adjusted to achieve the same overall flows without the auxiliary gas lines 156 (see Table 1) and with the auxiliary gas lines 156 (see Table 2). A flowrate of 1.00 is provided in Table 1 for each gas through each gas line 151A in order to simplify the example. No units are provided, but exemplary units could be based on mass of each gas per second or number of moles of each gas per second.

TABLE 1
Example Gas Flows with No Auxiliary Gas Provided.

| | Gas | Gas | Gas | Gas | Gas |
|---|---|---|---|---|---|
| | Line | Line | Line | Line | Line |
| | 151A | 151B | 151C | 151D | 151E |
| Gas 1 | 1.00 | 1.00 | 1.00 | 1.00 | 1.00 |
| Flowrate- | | | | | |
| Silane | | | | | |
| Gas 2 | 1.00 | 1.00 | 1.00 | 1.00 | 1.00 |
| Flowrate - | | | | | |
| Phosphene | | | | | |
| Carrier Gas | 1.00 | 1.00 | 1.00 | 1.00 | 1.00 |
| Flowrate | | | | | |
| Total Flowrate | 3.00 | 3.00 | 3.00 | 3.00 | 3.00 |

TABLE 2
Example Gas Flows with Auxiliary Gas Provided

| | Gas | Gas | Gas | Gas | Gas |
|---|---|---|---|---|---|
| | Line | Line | Line | Line | Line |
| | 151A | 151B | 151C | 151D | 151E |
| Gas 1 Flowrate | 0.97 | 0.98 | 0.95 | 0.99 | 0.96 |
| Silane From | | | | | |
| Main Gas Line 144 | | | | | |
| Gas 2 Flowrate | 0.97 | 0.98 | 0.95 | 0.99 | 0.96 |
| Phosphene From | | | | | |
| Main Gas Line 144 | | | | | |
| Carrier Gas | 0.97 | 0.98 | 0.95 | 0.99 | 0.96 |
| Flowrate From | | | | | |
| Main Gas Line 144 | | | | | |
| Gas 1 Flowrate | 0.09 | 0.06 | 0.00 | 0.00 | 0.00 |
| Silane From | | | | | |
| Auxiliary Gas Line | | | | | |
| Auxiliary Gas 2 | 0.00 | 0.00 | 0.00 | 0.03 | 0.12 |
| Flowrate Phosphene | | | | | |
| From Auxiliary | | | | | |
| Gas Line | | | | | |
| Auxiliary Carrier | 0.00 | 0.00 | 0.15 | 0.00 | 0.00 |
| Gas Flowrate From | | | | | |
| Auxiliary Gas Line | | | | | |
| Total Flowrate | 3.00 | 3.00 | 3.00 | 3.00 | 3.00 |

In Table 1, each gas from each gas source 141 is provided to each gas line 151 and gas injector 159 from the main gas line 144 at a flowrate of 1.00 with a total flowrate of 3.00 through each gas line 151 and gas injector 159. In Table 2, the flowrate of each gas from the main gas line 144 is reduced, and the flowrate of one of the gases from the auxiliary gas lines 156 is increased, so that the total flowrate through each gas line 151 and each gas injector 159 remains the same as Table 1. Adjusting the flowrates of different gases in a manner similar to Table 2 can be helpful when retrofitting an existing processing system to add auxiliary gas lines, such as the auxiliary gas lines 156 shown in FIG. 1B, so that the velocity profile of the gases remains highly similar to the velocity profile of the gases before the addition of the auxiliary gas lines.

The process chamber 101 further includes the exhaust channel 165. The exhaust channel 165 can extend through the liner 137 to provide a gas flow path out of the interior volume 110. In some embodiments, the exhaust channel is formed by surfaces of the liner 137. In some embodiments, the exhaust channel 165 can extend around a similar angular distance relative to the center 115C of the susceptor 115 as the angular distance that the gas injectors 159 extend around the center 115C of the susceptor 115, such as from about 60 degrees to about 120 degrees. The exhaust channel 165 is located on an opposing side of the interior volume 110 relative to the gas injectors 159. For example, a center of the exhaust channel 165 in the XY plane can be positioned about 180 degrees from the center of the gas injectors 159 in the XY plane when using the center 115C of the susceptor 115 as a reference point for the angular positions of the center of exhaust channel 165 and the center of the gas injectors 159.

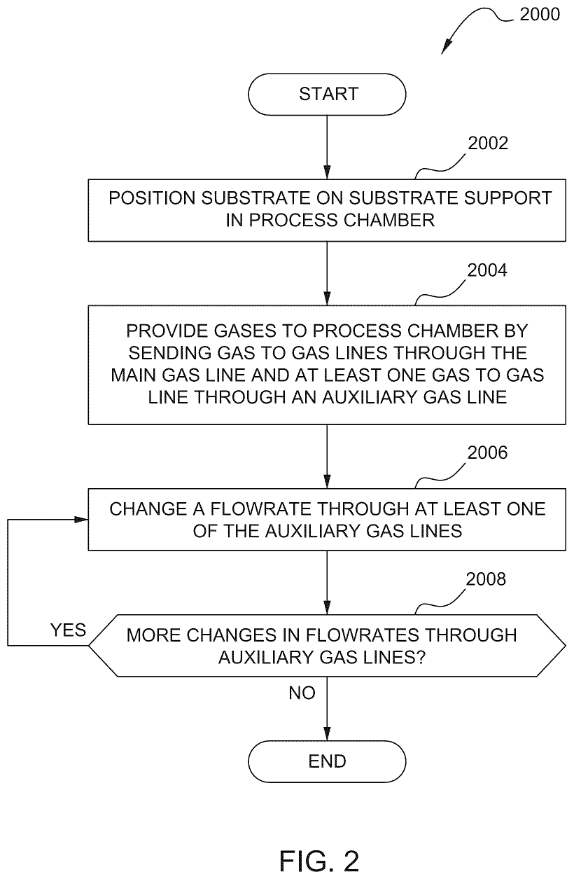

FIG. 2 is a process flow diagram of a method 2000 for processing a substrate 50 in the processing system 100 from FIG. 1A, according to one embodiment. The method 2000 can be executed by the controller 185. The method is described in reference to FIGS. 1A, 1B and FIG. 2.

The method 2000 begins at block 2002. Block 2002 is executed during a first time period. At block 2002 and with reference to FIGS. 1A and 1B, a substrate 50 is positioned on the susceptor 115.

At block 2004, gases are provided from the gas sources 141A, 141B, 141C to the main gas line 144 through the corresponding flow controllers 143A, 143B, 143C. The gases provided to the main gas line 144 are then provided to each of the gas lines 151. Also, at block 2004, gas is provided from one or more of the auxiliary gas lines 156 to one or more of the gas lines 151. In one embodiment, gas is provided from each auxiliary gas line 156 to each of the corresponding gas lines 151. The gases from the main gas line 144 and from the auxiliary gas lines 156 then flow through the gas lines 151 and into the interior volume 110 through the gas injectors 159.

At block 2006, a flowrate through at least one the auxiliary gas lines 156 is changed. This change can be (1) starting a flow through an auxiliary gas line 156, (2) stopping a flow through an auxiliary gas line 156, or (3) changing a flowrate through an auxiliary gas line 156.

As mentioned above, each flow controller described herein includes a valve (not separately shown). The controller 185 can be used to control the duration that each valve for the flow controllers 154 on the auxiliary gas lines 156 is opened during blocks 2004, 2006 as well as the degree of opening of the valves to control the flowrate. For example, in some embodiments, each valve on the auxiliary gas line 156 can be opened for a different duration relative to the other valves on the other auxiliary gas lines 156. Furthermore, each valve on the auxiliary gas lines 156 can be opened to a different degree, so that a different flowrate of gas can be provided through each auxiliary gas line 156. Additionally, in some embodiments, less than all of the auxiliary gas lines 156 are used to provide gas to the gas lines 151. For example, if there are only regions with a slower than targeted deposition rate and no regions with a faster than targeted deposition rate, then the flow controller 154C can cause the valve that is part of the flow controller 154C to remain closed, so that the carrier gas is not used to slow the process rate at any locations on the substrate 50.

Furthermore, in some embodiments, two or more gases can be provided to a gas line 151 through an auxiliary gas line 156. For example, as shown in FIG. 1B, the first precursor gas and the second precursor gas can be provided through corresponding auxiliary gas lines 156A, 156F to the first gas line 151A. Providing two precursor gases to one gas line 151 can be useful when the process rate is controlled more effectively by increasing the concentrations of two precursor gases as opposed to a single gas.

At block 2008, the controller 185 determines whether there should be any additional flowrate changes with the auxiliary gas line 156. If the controller 185 determines that one or more of the flowrates provided by the auxiliary gas lines 156 should be changed, then the controller can execute block 2006 again. Block 2008 can be repeated any number of times. The process gases from the gas lines 151 supplied from the main gas line 144 can continue to be provided to the interior volume 110 through the gas injectors 159 until the deposition is complete.

While the foregoing is directed to embodiments of the present disclosure, other and further embodiments of the disclosure may be devised without departing from the basic scope thereof, and the scope thereof is determined by the claims that follow.

1. A processing system comprising:
a process chamber comprising:
a chamber body disposed around an interior volume;
a substrate support positioned in the interior volume;
a plurality of gas injectors configured to direct gas into a first region of the interior volume, each gas injector positioned at a different angular location relative to a central vertical axis extending through a center of the substrate support; and
an exhaust channel configured to exhaust gas from a second region of the interior volume, the first region and the second region located on opposing sides of the central vertical axis; and
a gas supply system comprising
a main gas line coupled with a plurality of gas sources that include a first gas source and a second gas source;
a plurality of gas lines, each gas line of the plurality of gas lines coupled between the main gas line and one of the gas injectors; and
one or more auxiliary gas lines including a first auxiliary gas line coupled between the first gas source and a first gas line of the plurality of gas lines.

2. The processing system of claim 1, further comprising a second auxiliary gas line coupled between the second gas source and a first gas line of the plurality of gas lines.

3. The processing system of claim 1, further comprising, a second auxiliary gas line coupled between the second gas source and a second gas line of the plurality of gas lines.

4. The processing system of claim 1, wherein the plurality of gas lines includes five or more gas lines and the gas supply system further comprises a flow controller on each gas line of the plurality of gas lines.

5. The processing system of claim 1, wherein the one or more auxiliary gas lines includes five or more auxiliary gas lines and the gas supply system further comprises a flow controller on each auxiliary gas line of the one or more auxiliary gas lines.

6. The processing system of claim 1, further comprising a flow controller coupled between each gas source and the main gas line.

7. The processing system of claim 1, wherein the one or more auxiliary gas lines includes a plurality of auxiliary gas lines, wherein each auxiliary gas line is coupled between a gas source of the plurality of gas sources and a gas line of the plurality of gas lines.

8. The processing system of claim 1, wherein each gas line of the plurality of gas lines is configured to receive a same gas mixture from the main gas line at a main gas inlet and each auxiliary gas line is coupled with one of the gas lines of the plurality of gas lines at an auxiliary gas inlet that is downstream of the main gas inlet for that gas line.

9. A processing system comprising:
a process chamber comprising:
a chamber body disposed around an interior volume;
a substrate support positioned in the interior volume; and
a plurality of gas injectors configured to direct gas into the interior volume, each gas injector positioned at a different angular location relative to a central vertical axis extending through a center of the substrate support;
a gas supply system comprising
a main gas line coupled with a plurality of gas sources that include a first gas source and a second gas source;
a plurality of gas lines, each gas line of the plurality of gas lines coupled between the main gas line and one of the gas injectors; and
one or more auxiliary gas lines including a first auxiliary gas line coupled between the first gas source and a first gas line of the plurality of gas lines; and
a controller configured to:
provide a first gas from the first gas source and a second gas from the second gas source to the first gas line through the main gas line; and
provide the first gas from the first gas source to the first gas line through the first auxiliary gas line without going through the main gas line.

10. The processing system of claim 9, wherein a flowrate of the first gas through the first auxiliary gas line is from about 0.1% to about 10% of a total flowrate through the first gas line.

11. The processing system of claim 9, wherein the one or more auxiliary gas lines further includes a second auxiliary gas line coupled between the second gas source and the first gas line of the plurality of gas lines.

12. The processing system of claim 11, wherein the controller is further configured to provide the second gas from the second gas source to the first gas line through the second auxiliary gas line without going through the main gas line

13. The processing system of claim 11, wherein a flowrate of the second gas through the second auxiliary gas line is from about 0.1% to about 10% of a total flowrate through the first gas line.

14. The processing system of claim 9, wherein the one or more auxiliary gas lines further includes a second auxiliary gas line coupled between the second gas source and a second gas line of the plurality of gas lines.

15. The processing system of claim 14, wherein the controller is further configured to provide the second gas from the second gas source to the second gas line through the second auxiliary gas line without going through the main gas line.

16. The processing system of claim 15, wherein a flowrate of the second gas through the second auxiliary gas line is from about 0.1% to about 10% of a total flowrate through the second gas line.

17. A method of processing a substrate comprising:
positioning a substrate on a substrate support in an interior volume of a process chamber, the process chamber comprising a plurality of gas injectors configured to direct gas into the interior volume, each gas injector positioned at a different angular location relative to a central vertical axis extending through a center of the substrate support;
providing a mixture of a first gas from a first gas source and a second gas from a second gas source to a first gas line and a second gas line of a plurality of gas lines through a main gas line, wherein each gas line of the plurality of gas lines is coupled between the main gas line and one of the gas injectors;
providing the first gas from the first gas source to the first gas line through a first auxiliary gas line without having the flow from first auxiliary gas line go through the main gas line; and
directing a flow of the first gas and the second gas into the interior volume of the process chamber through the plurality of gas injectors.

18. The method of claim 17, wherein a flowrate of the first gas through the first auxiliary gas line is from about 0.1% to about 10% of a total flowrate through the first gas line.

19. The method of claim 18, further comprising providing the second gas from the second gas source to the second gas line through a second auxiliary gas line without having the flow from the second auxiliary gas line go through the main gas line, wherein a flowrate of the first gas through the first auxiliary gas line is from about 0.1% to about 10% of a total flowrate through the first gas line.

20. The method of claim 19, wherein the first gas provided through the first auxiliary gas line is used to increase a deposition rate of a deposition being performed on the substrate and the second gas provided through the second auxiliary gas line is used to decrease the deposition rate of the deposition being performed on the substrate.
